(19) United States
(12) Patent Application Publication
(10) Pub. No.: US 2011/0253311 A1
(43) Pub. Date: Oct. 20, 2011

(54) SUBSTRATE PROCESSING APPARATUS FOR PERFORMING PLASMA PROCESS

(75) Inventors: Sunao MURAOKA, Nirasaki-shi (JP); Jun Yamashita, Amagasaki-shi (JP); Atsushi Ueda, Amagasaki-shi (JP)

(73) Assignee: TOKYO ELECTRON LIMITED, Minato-ku (JP)

(21) Appl. No.: 13/175,469

(22) Filed: Jul. 1, 2011

Related U.S. Application Data
(62) Division of application No. 12/162,900, filed on Jul. 31, 2008.

(30) Foreign Application Priority Data
Jan. 31, 2006 (JP) 2006-023281
Mar. 13, 2006 (JP) 2006-067734

(51) Int. Cl. H01L 21/3065; C23C 16/511; C23C 16/50

(52) U.S. Cl. 156/345.41; 118/723 R; 118/723 AN; 156/345.51

(57) ABSTRACT

A substrate processing apparatus for performing a plasma process on a target substrate includes a process container configured to accommodate the target substrate. The apparatus includes a gas feed passage configured to supply a process gas into the process container and an exhaust passage configured to exhaust gas from inside the process container. The apparatus further includes a plasma generation mechanism configured to generate plasma of the process gas inside the process container and a metal component to be exposed to plasma inside the process container. The metal component is provided with a silicon film that coats at least a portion thereof to be exposed to plasma and to suffer an intense electric filed generated thereabout.

### CROSS-REFERENCE TO RELATED APPLICATIONS

This application is a divisional of U.S. application Ser. No. 12/162,900 filed Jul. 31, 2008, the entire contents of which are incorporated herein by reference. U.S. application Ser. No. 12/162,900 is a National Stage of Application No. PCT/JP07/51608 filed Jan. 31, 2007, which is based upon and claims the benefit of priority from prior Japanese Applications Nos. 2006-023281 and 2006-067734 filed Jan. 31, 2006 and Mar. 13, 2006, respectively.

### TECHNICAL FIELD

The present invention relates to a substrate processing apparatus for performing a process, such as a plasma process, on a target substrate, such as a semiconductor wafer, and a substrate table and a member to be exposed to plasma used for the same.

### BACKGROUND ART

Conventionally, in the process of manufacturing semiconductor devices, various substrate processes, such as film formation, etching, and ashing processes, are performed on a target object, such as a semiconductor wafer. The film formation process is exemplified by a thermal oxidation process, thermal nitridation process, plasma oxidation process, plasma nitridation process, and CVD.

In a substrate process of this kind, a predetermined substrate process is performed at a predetermined substrate temperature on a target substrate, such as a semiconductor wafer, placed on a substrate table disposed in a process container of a substrate processing apparatus. The substrate table is provided with a heater built therein to hold the target substrate at a predetermined substrate temperature, and is further provided with lifter pins for lifting the target substrate from the surface of the substrate table to assist loading and unloading of the target substrate to and from the substrate table, (see Jpn. Pat. Appln. KOKAI Publications No. 9-205130 and No. 2003-58700).

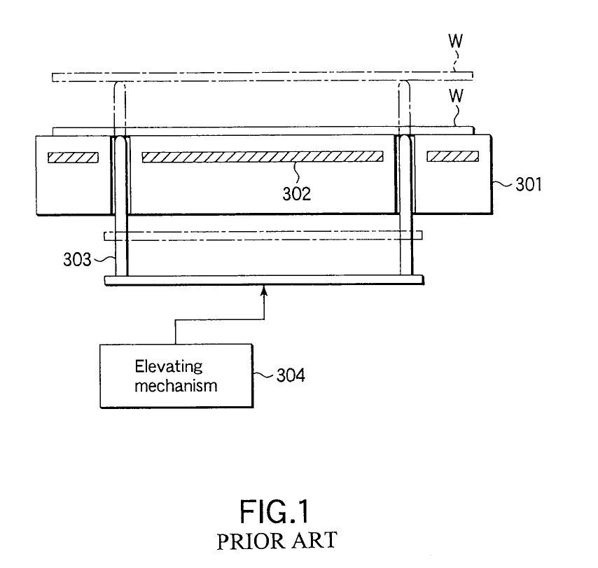

The structure of a substrate table conventionally used for substrate processing apparatuses will be explained below in detail with reference to FIG. 1. In general, a substrate table 301 is made of a ceramic, such as aluminum nitride (AlN), in which a heater 302 is embedded, for example. Further, lifter pins 303 made of, e.g., quartz glass are inserted and movable up and down in the substrate table 301. The lifter pins 303 are moved by an elevating mechanism 304 in the vertical direction, so that a target substrate W, such as a semiconductor wafer, is moved up and down.

Specifically, when the lifter pins 303 are set at the lower position, the target substrate W is placed on the surface of the substrate table 301. On the other hand, when the lifter pins 303 are set at the upper position indicated by chain lines, the target substrate W is transferred to and from the lifter pins 303 by an arm of a transfer mechanism (not shown). This substrate table 301 is applicable to various processing apparatuses, such as plasma processing apparatuses. For example, a plasma processing apparatus of this kind includes a planar antenna (slot antenna) having a number of slots, through which microwaves are radiated into a process container to generate microwave plasma. A plasma process is performed by use of this microwave plasma.

However, it has been found that the following problem is caused, where a plasma oxidation process is performed in a microwave plasma processing apparatus including, e.g., the slot antenna described above, while a target substrate is placed on the substrate table 301. Specifically, a lot of particles, such as several thousand particles having a diameter of 0.16 μm or more, are generated on the back side of the target substrate when it is unloaded from the table after the substrate process.

On the other hand, a plasma processing apparatus used as a substrate processing apparatus is structured such that a wall portion of the process container and members disposed in the process container are made of a metal, such as aluminum. When intense plasma comes into contact with some of these members, the plasma etches the surface of the members and generates particles, which cause metal contamination due to, e.g., aluminum to a large extent, thereby deteriorating the process. Further, the surface of the members is severely damaged or degraded particularly when the plasma acts on aluminum members, so the process reproducibility becomes lower with a lapse of time in using the apparatus.

As a technique for solving this problem, Jpn. Pat. Appln. KOKAI Publication No. 2002-353206 discloses a reaction chamber in which that part of the inner wall which faces the plasma generation field is formed of a silicon crystal body. According to this publication, the silicon crystal body is prepared by hollowing an ingot of mono-crystalline silicon.

However, where the wall portion of a reaction chamber is formed of a processed bulk body of mono-crystalline silicon, this part becomes very expensive but cannot have a sufficient strength, so this is not practical.

### DISCLOSURE OF INVENTION

An object of the present invention is to provide a substrate processing apparatus including a substrate table and also a substrate table used for the same, which can decrease particles to be generated on the back side of a target substrate placed on the substrate table.

Another object of the present invention is to provide a substrate processing apparatus including a member to be exposed to plasma inside a process container and also a member to be exposed to plasma used for the same, which can practically prevent the member from causing metal contamination.

According to a first aspect of the present invention, there is provided a substrate table comprising: a substrate table main body provided with a heater embedded therein and having an upper surface serving as a heating face for heating a target substrate; and lifter pins inserted in the substrate table main body and configured to be moved up and down, wherein recessed portions are formed in the heating face of the substrate table main body at positions corresponding to the lifter pins and have a bottom lower than the heating face, each of the lifter pins includes a lifter pin main body and a head portion formed at a distal end of the lifter pin main body and having a diameter larger than the lifter pin main body, the head portion being formed to correspond to each recessed portion and to be partly accommodated in the recessed portion, the head portion has a head portion upper end for supporting the target substrate and a head portion lower surface opposite to the head portion upper end, and the lifter pins are movable between a first state where the head portion lower surface engages with the bottom of the recessed portion, and a second state where the head portion lower surface separates upward from the bottom of the recessed portion.

In the first aspect, the first state is preferably preset such that the head portion upper end is distant from the upper surface of the substrate table by a distance of more than 0.0 mm and 0.5 mm or less, more preferably of more than 0.1 mm or more and 0.4 mm or less, and furthermore preferably of more than 0.2 mm or more and 0.4 mm or less.

In the first aspect, the substrate table may be arranged such that the substrate table main body consists essentially of aluminum nitride, and the lifter pins consist essentially of quartz glass.

According to a second aspect of the present invention, there is provided a substrate processing apparatus comprising: a substrate process chamber configured to be exhausted by an exhaust system; a substrate table disposed inside the substrate process chamber and configured to support and heat a target substrate; and a gas supply system configured to supply a process gas into the substrate process chamber, the substrate table comprising a substrate table main body provided with a heater embedded therein and having an upper surface serving as a heating face for heating the target substrate, and lifter pins inserted in the substrate table main body and configured to be moved up and down, wherein recessed portions are formed in the heating face of the substrate table main body at positions corresponding to the lifter pins and have a bottom lower than the heating face, each of the lifter pins includes a lifter pin main body and a head portion formed at a distal end of the lifter pin main body and having a diameter larger than the lifter pin main body, the head portion being formed to correspond to each recessed portion and to be partly accommodated in the recessed portion, the head portion has a head portion upper end for supporting the target substrate and a head portion lower surface opposite to the head portion upper end, and the lifter pins are movable between a first state where the head portion lower surface engages with the bottom of the recessed portion, and a second state where the head portion lower surface separates upward from the bottom of the recessed portion.

The substrate processing apparatus may be a plasma processing apparatus. The substrate processing apparatus may comprise a dielectric body window formed on the substrate process chamber at a position to face the target substrate placed on the substrate table, and an antenna disposed outside the substrate process chamber and coupled with the dielectric body window. In this case, the antenna may be a planar antenna with a plurality of slots formed therein and configured to supply microwaves from the slots into the process container. The substrate processing apparatus may be one of an oxidation processing apparatus, nitridation processing apparatus, etching apparatus, and CVD apparatus.

According to a third aspect of the present invention, there is provided a substrate processing apparatus comprising: a process container configured to accommodate a target substrate, and a plasma generation mechanism configured to generate plasma inside the process container, so as to perform a predetermined plasma process on the target substrate inside the process container, wherein a portion to be exposed to plasma inside the process container is at least partly coated with a silicon film.

In this case, the portion to be exposed to plasma may comprise a surface of a metal main body coated with the silicon film.

According to a fourth aspect of the present invention, there is provided a substrate processing apparatus comprising: a process container configured to accommodate a target substrate; a plasma generation mechanism configured to generate plasma inside the process container; and a member to be exposed to plasma inside the process container, so as to perform a predetermined plasma process on the target substrate inside the process container, wherein the member to be exposed to plasma comprises a metal main body and a silicon film that coats the metal main body at least a portion to be exposed to plasma.

According to a fifth aspect of the present invention, there is provided a substrate processing apparatus comprising: a process container configured to accommodate a target substrate; a microwave generator configured to generate microwaves; a waveguide configured to transmit microwaves generated by the microwave generator toward the process container; a microwave feeder mechanism disposed on an upper side of the process container and configured to feed the microwaves into the process container; a support member configured to support the microwave feeder mechanism from inside the process container so as for the microwave feeder mechanism to face the target substrate accommodated inside the process container, the support member including a metal main body at least part of which is positioned in a plasma generation field and is coated with a silicon film; and a process gas supply mechanism configured to supply a process gas at a position inside the process container and directly blow the microwave feeder mechanism, wherein a plasma process is performed on the target substrate by use of plasma of the process gas generated by the microwaves inside the process container.

In this case, the microwave feeder mechanism may comprise an antenna configured to radiate microwaves and a transmission member consisting essentially of a dielectric body and configured to transmit microwaves radiated from the antenna into the process container, and the support member may support the transmission member.

According to a sixth aspect of the present invention, there is provided a member to be exposed to plasma inside a process container of a substrate processing apparatus in which a plasma process is performed on a target substrate by use of plasma generated inside the process container accommodating the target substrate, the member to be exposed to plasma comprising: a metal main body and a silicon film that coats the metal main body at least a portion to be exposed to plasma.

In the third to sixth aspects the main body may consist essentially of aluminum. The silicon film is preferably a film formed by thermal spraying. The silicon film preferably has a thickness of 1 to 100 μm.

According to the first and second aspects of the present invention, in a state where the lifter pins is set in the first state on the lower side, the target substrate is held by the lifter pins to be separated from the upper surface of the substrate table. Consequently, the target substrate does not come into direct contact with the substrate table surface, so the particle generation due to this contact is prevented. In this case, the distance of the target substrate from the upper surface of the substrate table in the first state may be set to be within 0.4 mm, so that the uniformity of temperature distribution during a substrate process is kept high.

According to the third to sixth aspects of the present invention, a portion to be exposed to plasma inside the process container is at least partly coated with a silicon film. Typically, a member to be exposed to plasma inside the process container comprises a metal main body and a silicon film that coats the metal main body at least a portion to be exposed to plasma. In this case, the silicon is mainly worn out by plasma, and the aluminum or the like of the metal main body can be hardly worn out, so metal contamination due to e.g., aluminum becomes very few. Further, since formation of the film on the main body of e.g., aluminum is only required, the structure can be provided at a relatively low cost. In addition, the main body is made of a metal, so the sufficient strength is ensured.

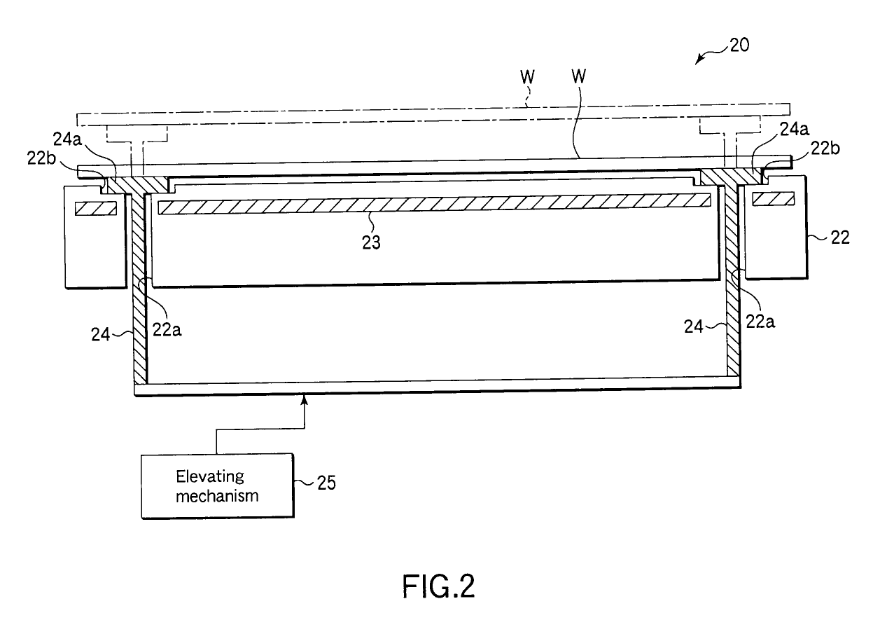

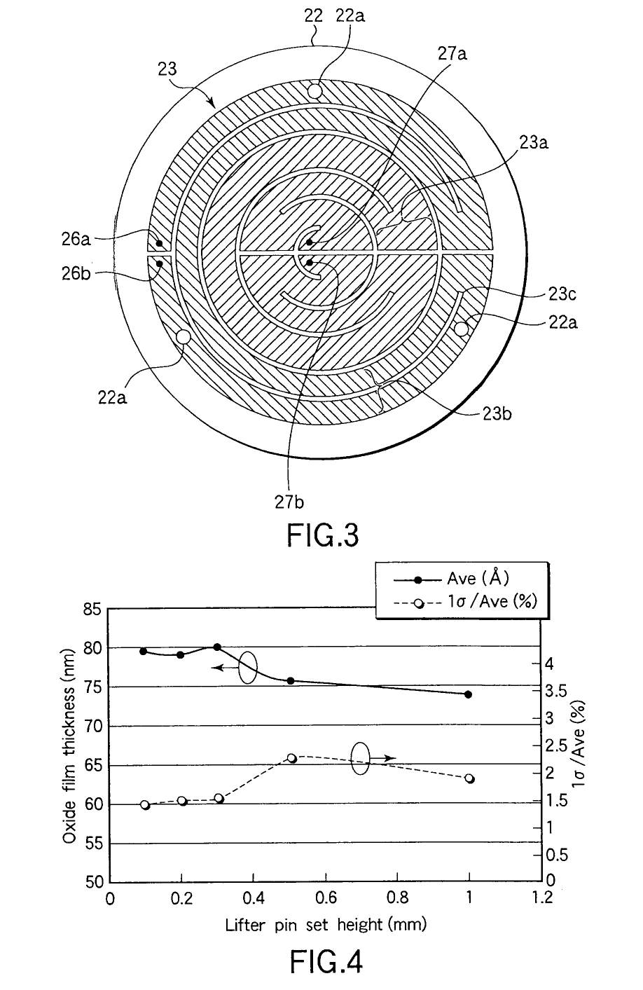

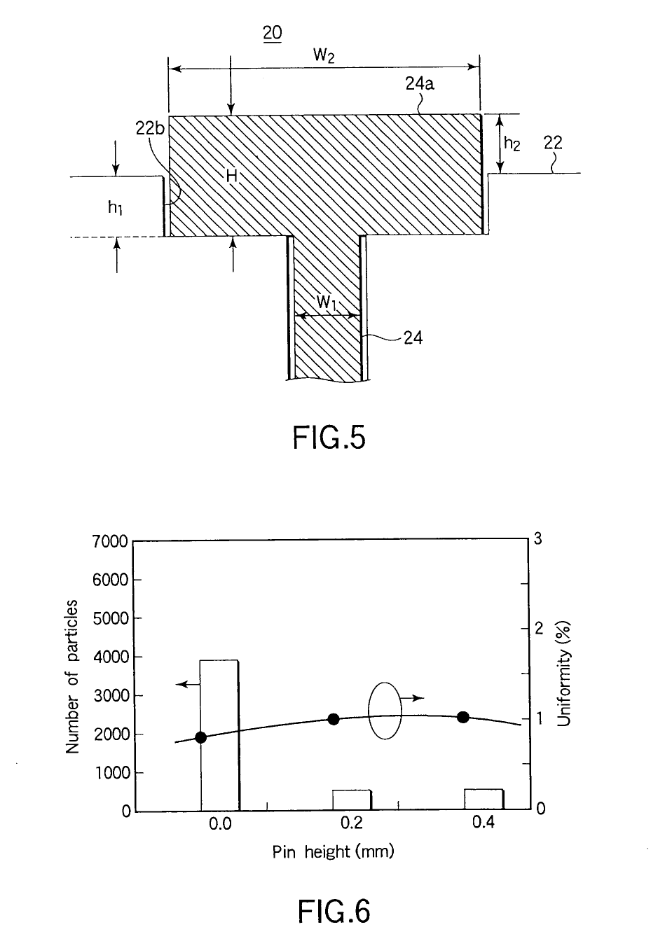

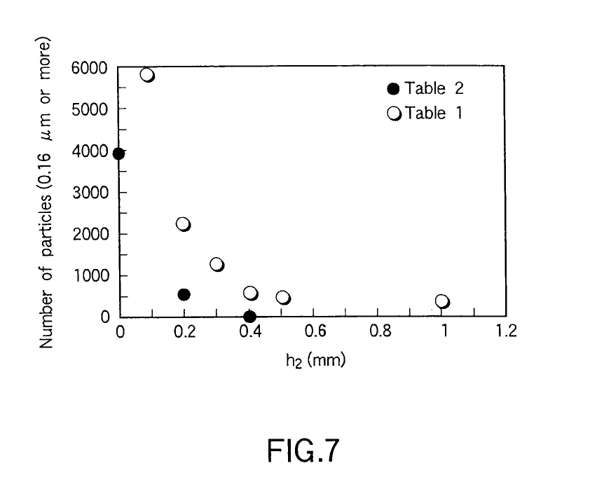

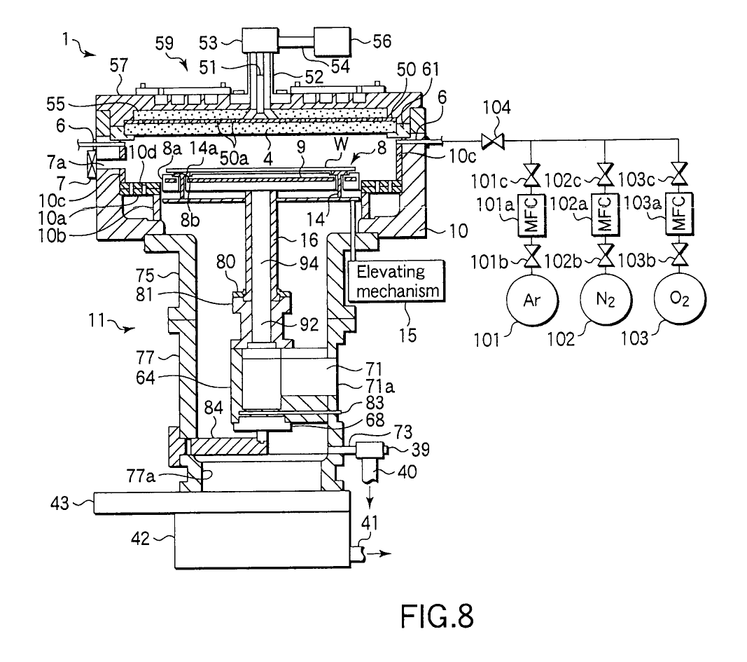

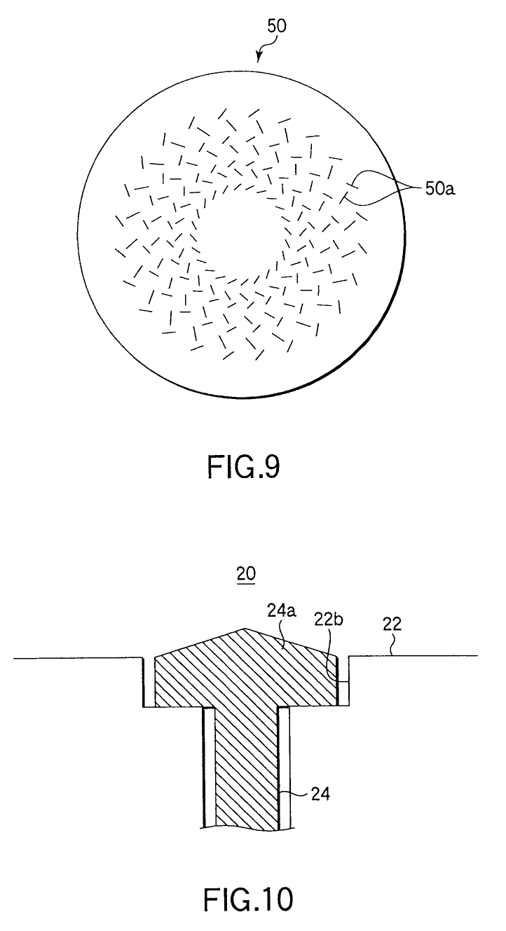

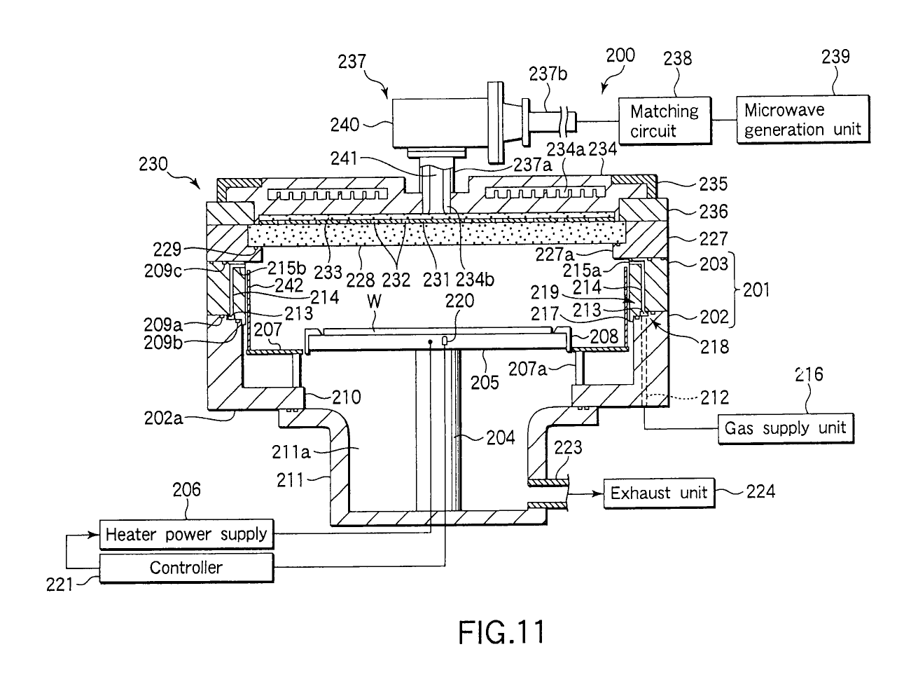

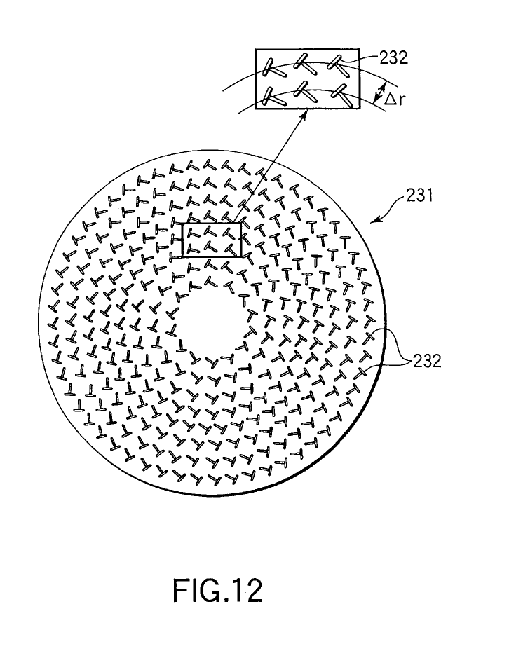

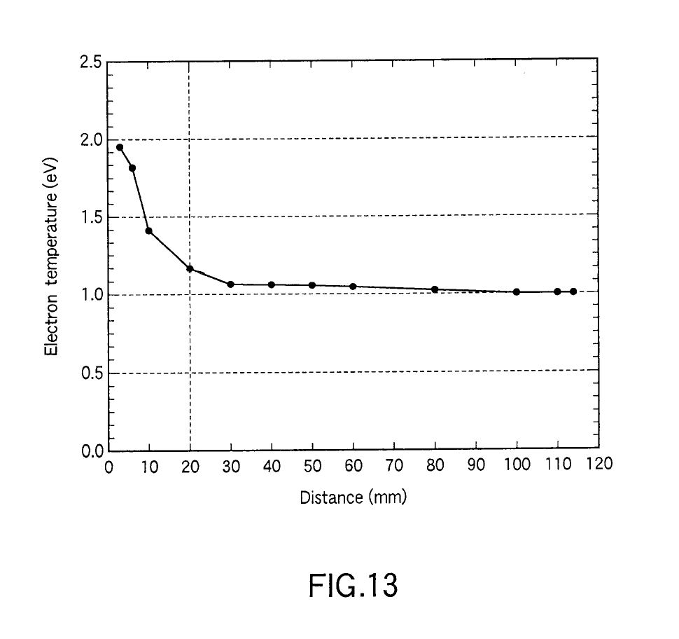

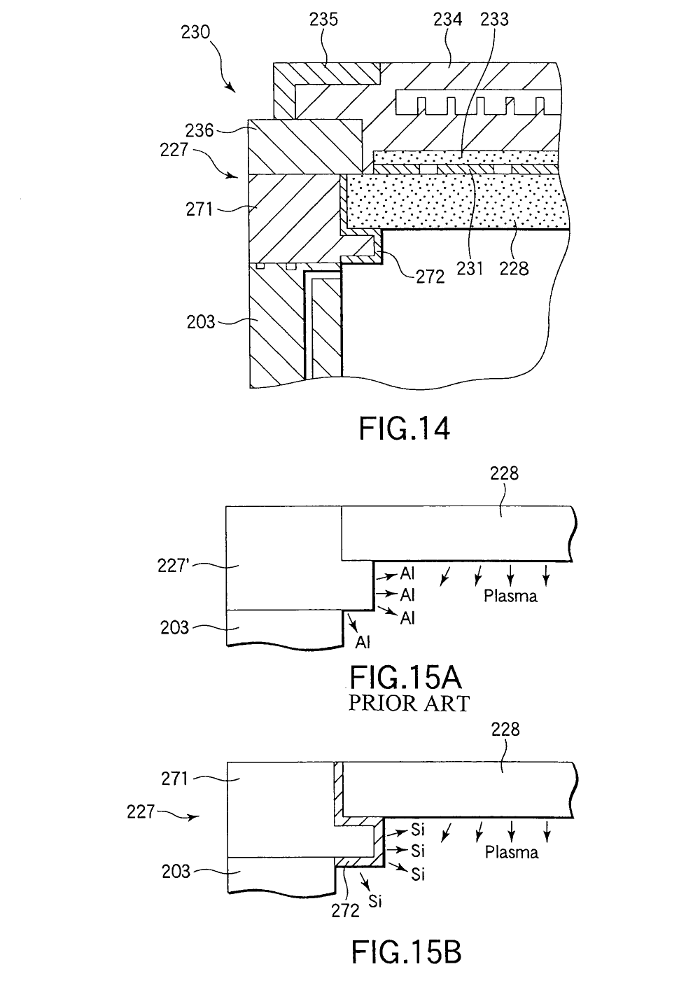

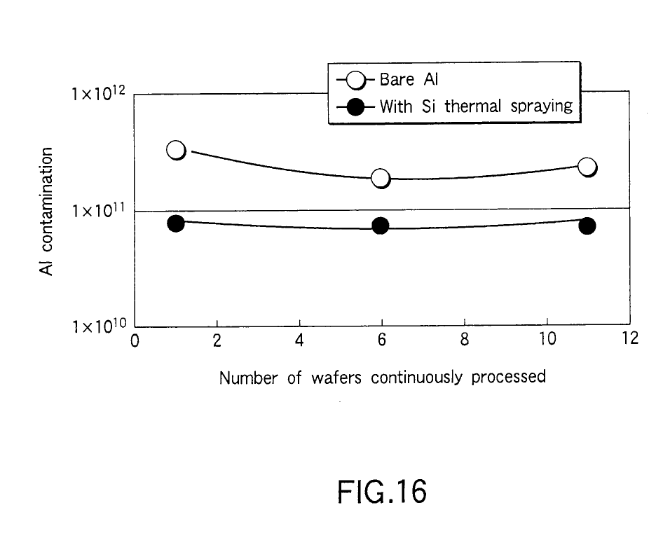

### BRIEF DESCRIPTION OF DRAWINGS

[FIG. 1] This is a view showing the structure of a conventional substrate table.

[FIG. 2] This is a sectional view showing the structure of a substrate table according to a first embodiment of the present invention.

[FIG. 3] This is a plan view of the substrate table shown in FIG. 2.

[FIG. 4] This is a diagram showing an experiment used as a base in the first embodiment of the present invention.

[FIG. 5] This is an enlarged view showing part of the substrate table shown in FIG. 3.

[FIG. 6] This is a diagram showing another experiment used as a base in the first embodiment of the present invention.

[FIG. 7] This is a diagram showing an effect of the first embodiment of the present invention.

[FIG. 8] This is a sectional view showing a microwave plasma processing apparatus using a substrate table according to the first embodiment of the present invention.

[FIG. 9] This is a plan view showing a planar antenna used in the microwave plasma processing apparatus shown in FIG. 8.

[FIG. 10] This is a view showing a modification of lifter pins used in a substrate table according to the first embodiment of the present invention.

[FIG. 11] This is a sectional view schematically showing a plasma processing apparatus according to a second embodiment of the present invention.

[FIG. 12] This is a view showing the structure of a planar antenna member used in the plasma processing apparatus shown in FIG. 11.

[FIG. 13] This is a view showing the relationship between the distance from a transmission plate and the electron temperature of plasma.

[FIG. 14] This is an enlarged view showing an upper plate used in the plasma processing apparatus shown in FIG. 11.

[FIG. 15A] This is a schematic view showing wear-out of a conventional upper plate due to plasma.

[FIG. 15B] This is a schematic view showing wear-out of the upper plate due to plasma in the plasma processing apparatus shown in FIG. 11.

[FIG. 16] This is a graph showing a difference in aluminum contamination between the presence and absence of a silicon film on an upper plate where a plasma process is continuously performed.

### BEST MODE FOR CARRYING OUT THE INVENTION

Embodiments of the present invention will now be described with reference to the accompanying drawings.

### First Embodiment

First, a substrate table according to a first embodiment of the present invention will be explained in detail with reference to FIGS. 2 and 3. FIG. 2 is a sectional view showing a substrate table according to this embodiment. FIG. 3 is a plan view of the substrate table shown in FIG. 2. This substrate table may be applied to various substrate processing apparatuses for performing respective processes, such as film formation, etching, and ashing processes. The film formation process is exemplified by a thermal oxidation process, thermal nitridation process, plasma oxidation process, plasma nitridation process, and CVD.

As shown in FIG. 2, a substrate table 20 includes a substrate table main body 22 made of a ceramic material, such as aluminum nitride, in which a heater 23 having a concentric or spiral format is embedded, as shown in FIG. 3. The substrate table main body 22 has through holes 22a formed therein at three positions to insert lifter pins 24 therein. The lifter pins 24 are made of Al₂O₃, AlN, or quartz glass in light of corrosion resistance and heat resistance. The lifter pins 24 can be moved up and down by an elevating mechanism 25 of the electric or pneumatic driver type between a lower position indicated by solid lines and an upper position indicated by chain lines in FIG. 2

In the structure shown in FIG. 2, a target substrate W, such as a semiconductor wafer, is supported by the lifter pins 24 such that the back side of the target substrate W does not come into contact with the upper surface of the substrate table main body 22 even when the lifter pins 24 are set at the lower position. However, in this state, the upper surface of the substrate table main body 22 serves as a heating face for heating the target substrate W. On the other hand, when the lifter pins 24 are set at the upper position, the target substrate W is positioned far above the upper surface of the substrate table main body 22, so that a space is formed between the target substrate W and substrate table main body 22 to allow a robot arm of a substrate transfer mechanism (not shown) to be inserted therein.

As exemplified in FIG. 3, the heater 23 is formed of a patterned planar heater including an inner heater portion 23a and an outer heater portion 23b, which are activated independently of each other in operation. The inner heater portion 23a and outer heater portion 23b have been prepared from a metal material, such as W or Mo, by patterning with insulating spaces or slits 23c to separate the portions 23a and 23b from each other. The patterning may be realized by vapor deposition or processing of a plate. The inner heater portion 23a is connected at an in-contact 26a and an out-contact 26b to power feed lines (not shown) extending from a power supply for supplying a driving current. Similarly, the outer heater portion 23b is connected at an in-contact 27a and an out-contact 27b to power feed lines (not shown) extending from a power supply for supplying a driving current. In the plan view shown in FIG. 3, the three through holes 22a are separated from each other at an angle of about 120°, and thus the three lifter pins 24 inserted in these holes are separated from each other at an angle of about 120°.

As described above, in the conventional substrate table, where a target substrate is processed in a suitable processing apparatus while a target substrate is placed on the substrate table, a problem arises such that a lot of particles are generated on the back side of the target substrate. It is thought that such particle generation is mainly caused by a positional shift of the target substrate and sticking of deposits on the target substrate, because the target substrate is set in direct contact with the surface of the substrate table.

In light of the problem described above, in the process of developing the present invention, the inventors conducted researches while using the conventional substrate table shown in FIG. 1 in various processing apparatuses, such as plasma processing apparatuses. Particularly, a plasma processing apparatus used in the researches was provided with a planar antenna (slot antenna) having a number of slots, through which microwaves were radiated into a process container to generate microwave plasma, thereby performing a plasma process by use of this microwave plasma. The lifter pins was set at different heights when a substrate process was performed on the target substrate, to examine the state of particle generation and the uniformity of a film formed on the surface of the target substrate by the substrate process.

In this process experiment, a silicon wafer (substrate) was used as the target substrate W, and a silicon oxide film was formed on the silicon substrate to have a thickness of 7 to 8 nm under the following conditions. Specifically, at a pressure of 133.3 Pa and a substrate temperature of 400° C., Ar gas was supplied at a flow rate of 500 mL/min (sccm), and oxygen gas and hydrogen gas were supplied each at a flow rate of 5 mL/min (sccm). Further, microwaves having a frequency of 2.45 GHz were supplied from the microwave antenna at a power of 4,000 W. Table 1 set out below shows results of this process experiment, and specifically shows the lifter pin height, the number of particles deposited on the back side of the silicon substrate, the average film thickness of a silicon oxide film formed on the front side of the target substrate, and the film thickness uniformity thereof (1σ value/average film thickness). In Table 1, the pin height denotes a protrusion height of the lifter pins protruding from the substrate table surface, and this is not an actual height but an input set value input into the elevating mechanism.

TABLE 1

| | | | | | |
|---|---|---|---|---|---|
| Pin height (mm) | 0.1 | 0.2 | 0.3 | 0.5 | 1.0 |
| Number of particles | 5,813 | 2,239 | 1,273 | 463 | 350 |
| Film thickness (nm) | 7.94 | 7.93 | 7.97 | 7.57 | 7.43 |
| 1σ/average (%) | 1.40 | 1.46 | 1.50 | 2.3 | 1.95 |

As show in Table 1, where the lifter pin set height was 0.1 mm, 5,813 particles having a diameter of 0.16 μm or more were observed on the back side of the silicon substrate. However, where the lifter pin set height was 0.2 mm, the number of particles was decreased to 2,239. Further, where the set height was 0.3 mm, the number of particles was decreased to 1,273. Where the set height was 0.5 mm, the number of particles was decreased to 463. Furthermore, where the set height was 1.0 mm, the number of particles was decreased to 350.

As described above, it has been confirmed that, where the elevating mechanism is controlled for the lifter pins to protrude from the substrate table surface even in the substrate process, particle generation on the back side of the target substrate is suppressed. However, where the target substrate W is held separately from the substrate table surface (i.e., heating face) in the substrate process, as described above, the film formation uniformity on the front side of the target substrate may be degraded if the distance between the back side of the target substrate and the heating face is too large.

In this respect, as shown in Table 1, where the lifter pin set height was 0.1 mm, the film thickness uniformity of a formed silicon oxide film was 1.4%. However, where the lifter pin set height was 0.2 mm, the film thickness uniformity of a formed silicon oxide film was 1.46%. Further, where the set height was 0.3 mm, the uniformity was 1.5%. Where the set height was 0.5 mm, the uniformity was 2.3%. Furthermore, where the set height was 1.0 mm, the uniformity was 1.95%. FIG. 4 is a diagram showing the relationship between the lifter pin set height and average film thickness and the relationship between the lifter pin set height and film thickness uniformity.

As shown in Table 1 and FIG. 4, with an increase in the lifter pin set height, fluctuations in the film thickness were increased.

Specifically, it has been found that, where the target substrate is set to be out of contact with the substrate table, e.g., where the target substrate is held on the lifter pins to be separate from the substrate table even in the substrate process, the particle generation on the back side of the target substrate can be prevented. Further, it has been found that, with an increase in the distance between the target substrate and substrate table in the substrate process, the substrate process uniformity is degraded. The latter is caused by a noticeable deterioration in the substrate temperature distribution, because radiant heat from the substrate is decreased and the substrate temperature is lowered with an increase in the distance between the substrate table and substrate. Further, according to the present invention, as shown in FIG. 4, it has been found that the substrate process uniformity is drastically changed or deteriorated when the lifter pin set height exceeds about 0.3 mm.

As described above, the lifter pin height is a lifter pin set height set in the substrate elevating mechanism and thus is not necessarily equal to the actual protrusion height of the lifter pins on substrate table. Consequently, where the conventional substrate table shown in FIG. 1 is used and the protrusion length of the lifter pins is controlled by the substrate elevating mechanism, the target substrate may come into contact with the substrate table surface in practice. In order to reliably avoid this problem, the protrusion length of the lifter pins has no other choice than to be set needlessly larger, just to be on the safe side. However, where the protrusion length of the lifter pins is set larger like this, the particle generation on the back side of the target substrate is suppressed, but the substrate process uniformity is difficult to ensure at the same time. A substrate table having a surface with protrusions directly formed thereon may be adopted, but such a table is very difficult to fabricate in light of machining accuracy.

According to the present invention made in light of this problem, as shown in FIG. 2, recessed portions 22b are formed in the surface of the substrate table main body 22. Further, head portions 24a are respectively formed on the distal ends of the lifter pins 24, so that they are partly accommodated in the recessed portions 22b when the lifter pins 24 are set at the lower position.

FIG. 5 is an enlarged view showing the head portion 24a set in the lowered state. As shown in FIG. 5, the recessed portion 22b formed in the surface of the substrate table main body 22 for partly accommodating the head portion 24a has a depth h₁. When the head portion 24a is set in the lowered state, the head portion 24a sits in the recessed portion 22b while the bottom of the head portion 24a is placed on the bottom of the recessed portion 22b. The shape of the head portion 24a is preferably rectangular or circular, and particularly preferably circular. Typically, each of the lifter pins 24 has a diameter W₁ of 2 to 3 mm, and the head portion 24a has a diameter W₂ of about 10 mm. The diameter W₁ should not be too larger, because the temperature distribution can be degraded depending on this diameter. The diameter W₁ is preferably set to be 15 mm or less.

The head portion 24a has a height H larger than the depth h₁ of the recessed portion 22b, and thus the head portion 24a protrudes upward from the surface of the substrate table main body 22 by a height of H−h₁ (=h₂).

Table 2 and FIG. 6 show the number of particles having a diameter of 0.16 μm or more generated on the back side of the target substrate W, the film thickness of a silicon oxide film formed on the front side of the target substrate W, and the film thickness uniformity of the silicon oxide film, where the protrusion height h₂ was set at different values in the substrate table main body 22. In the experiment concerning Table 2 and FIG. 6, a silicon oxide film was formed under the same conditions as those described above.

TABLE 2

| | | | | |
|---|---|---|---|---|
| Pin height (mm) | —* | 0.0 | 0.2 | 0.4 |
| Number of particles | 119 | 3,888 | 536 | 572 |
| Film thickness (nm) | — | 8.02 | 7.89 | 7.76 |
| 1σ/average (%) | — | 0.85 | 1.02 | 1.04 |

*The substrate was transferred only to TN and not into the process container.

In Table 2, a sample indicated with a symbol “*” denotes a comparison reference experiment in which the target substrate W was transferred only to the transfer module and not into the process container. In this case, the number of particles having a diameter of 0.16 μm or more generated on the back side of the target substrate W was only 119.

However, where the protrusion height h₂ was 0.0 mm, i.e., the target substrate W was set in direct contact with the surface of the substrate table main body 22, the number of particles generated on the back side of the target substrate W reached 3,888.

On the other hand, where the protrusion height h₂ of the head portion 24a was 0.2 mm and 0.4 mm, the number of particles was 536 and 572, respectively, i.e., the particle generation was effectively suppressed.

Further, as regards the film thickness uniformity (1σ value/average film thickness), as shown in Table 2, where the head portion protrusion height h₂ was 0.4 mm, the film thickness uniformity was also good with a film thickness fluctuation of 1.04%. As described above, it has been found that, where the head portion protrusion height h₂ is within a range of 0.2 to 0.4 mm, the number of particles can be suppressed, while the film thickness uniformity can be improved. The head portion protrusion height of 0.2 to 0.4 mm corresponds to the warp amount of the target substrate W. It is thought that, where the head portion protrusion height is set to be within this range, the target substrate is prevented from coming into contact with the surface of the substrate table main body 22 even if the target substrate is warped.

Further, as shown in FIGS. 2 and 5, according to the substrate table 20, the head portion 24a engages with the recessed portion 22b formed in the substrate table main body 22, and the protrusion height of the head portion 24a is automatically determined, so that the head portion protrusion height h₂ is reliably and accurately determined. In this case, for example, the head portion protrusion height h₂ can be set to be more than 0.0 mm, such as within a range of 0.1 to 0.5 mm, so that the number of particles is further effectively decreased while the film formation is further uniformly performed.

FIG. 7 is a diagram showing the effect of decreasing the number of particles realized by the substrate table 20 shown in FIGS. 2 and 5, in comparison with the effect of decreasing the number of particles realized by the conventionally substrate table 301 shown in FIG. 1 where the conventional lifter pins 303 having no head portions were positionally controlled by the elevating mechanism 304. FIG. 7 is associated with Tables 1 and 2, wherein the symbol “” corresponds to Table 2 obtained by use of the substrate table 20 shown in FIGS. 2 and 5, and the symbol “◯” corresponds to Table 1 obtained by use of the conventional substrate table 301 shown in FIG. 1.

As shown in FIG. 7, where the protrusion length of the head portion 24a was accurately controlled within a range of 0.1 to 0.5 mm in accordance with the present invention, particle generation was effectively suppressed, as compared to the conventional case. It should be noted that, in the present invention, the head portion 24a of each of the lifter pins 24 mechanically engaged with the recessed portion 22b formed in the substrate table main body. On the other hand, in the conventional case, the protrusion length of the lifter pins having no head portions was controlled by the driving mechanism.

Next, an explanation will be given of a substrate processing apparatus, to which the substrate table described above is applied. FIG. 8 is a sectional view showing a microwave plasma processing apparatus or substrate processing apparatus using a substrate table having the structure described above.

As shown in FIG. 8, the microwave plasma processing apparatus 1 includes a cylindrical process container 10 having an opening portion at the top. The process container 10 is made of a conductive member, such as a metal, e.g., aluminum or stainless steel, or an alloy thereof.

The opening portion at the top of the process container 10 is provided with a dielectric body plate 4 formed of a flat plate. For example, the dielectric body plate 4 is made of quartz or ceramic and having a thickness of about 20 to 30 mm. At the interface between the process container 10 and dielectric body plate, a seal member (not shown), such as an O-ring, is interposed to ensure that this interface is airtight. The dielectric body plate 4 is supported by a ring upper plate 61.

A planar antenna, such as a radial line slot antenna 50 having a plurality of slots 50a, is disposed on the upper side of the dielectric body plate 4. The slot antenna 50 is connected to a microwave generation unit 56 through a waveguide 59 formed of a waveguide tube 52, a mode transducer 53, and a rectangular waveguide tube 54. The microwave generation unit 56 includes a microwave generator, which generates microwaves of 300 MHz to 30 GHz, such as 2.45 GHz. A wave-retardation body 55 is disposed on the upper side of the slot antenna 50 and made of a dielectric body, such as a laminated body of quartz, ceramic, and fluorocarbon resin. A conductive cover 57 having a cooling jacket is disposed on the upper side of the wave-retardation body 55. The conductive cover 57 is configured to shield microwaves and to efficiently cool the slot antenna 50 and dielectric body plate 4. The rectangular waveguide may be provided with a matching circuit (not shown) thereon for impedance matching to improve the electric power use efficiency.

An axial portion 51 made of a conductive material extends inside the waveguide tube 52 and is connected to the center of the upper surface of the slot antenna 50. Hence, the waveguide tube 52 is structured as a coaxial waveguide tube to generate an RF (radio frequency) electromagnetic field inside the process container 10 by radiation through the dielectric body plate 4. The slot antenna 50 is separated and protected from the process container 10 by the dielectric body plate 4. Consequently, the slot antenna 50 cannot be exposed to plasma.

FIG. 9 is a plan view showing the structure of the slot antenna 50 in detail. As shown in FIG. 9, a number of slots 50a are concentrically formed in the slot antenna 50 while adjacent slots 50a are set at right angles to form a T-shape.

An exhaust section 11 is connected to the bottom of the process container 10. The exhaust section 11 includes hollow and airtight exhaust pipes 75 and 77. The bottom of the exhaust pipe 77 is connected to a turbo molecular pump 42 through a valve 43. The valve 43 is formed of a pressure control valve, such as a switching valve or APC valve. A flange 77a is disposed below the exhaust pipe 77 and has a rough exhaust port 73 formed in the sidewall to roughly exhaust gas from inside the process container 10. The rough exhaust port 73 is connected to a vacuum pump (not shown) through a valve 39 and a rough exhaust line 40, and this vacuum pump is connected to an exhaust line 41 of the turbo molecular pump 42.

The interior of the process container 10 can be set at a predetermined vacuum level by exhausting gas therefrom by the turbo molecular pump 42 through the rough exhaust line 40. The process container 10 is provided with a gas injector 6 disposed in the sidewall at an upper position to supply various process gases into the process container 10. In this embodiment, the gas injector 6 is formed of a ring with gas holes equidistantly formed therein on the inner side. Alternatively, the gas injector 6 may be formed of a nozzle or shower structure.

The gas injector 6 is connected to a rare gas (such as Ar) source 101, a nitrogen gas source 102, and an oxygen gas source 103 through respective mass-flow controllers (MFC) 101a, 102a, and 103a, respective valves 101b, 101c, 102b, 102c, 103b, and 103c, and a common valve 104. The gas injector 6 has a number of gas delivery ports formed therein to surround the table 8, as described later, so that each of Ar gas, nitrogen gas, and oxygen gas can be uniformly supplied into the process space inside the process container 10.

The process gases are not limited to those described above, and various gases may be used in accordance with processes. Consequently, for example, gas sources of hydrogen, ammonia, NO, N₂O, H₂O, and an etching gas, such as a CF family gas, may be disposed.

The process container 10 is provided with a substrate table 8 located therein for placing a target substrate W, such as a semiconductor wafer. The upper surface of the substrate table 8 preferably has a recessed area (counter-bore area) formed therein at an area concentrically with and slightly larger than the outer diameter of the target substrate W, such as a semiconductor wafer, and having a depth of, e.g., about 0.5 to 1 mm, so that the target substrate is prevented from causing a positional shift. However, for example, where an electrostatic chuck is used, the recessed area may be omitted because the target substrate is held by an electrostatic force. The substrate table 8 includes a substrate table main body 8a, lifter pins 14 inserted in the substrate table main body 8a to move up and down the target substrate or semiconductor wafer W, and an elevating mechanism 15 to move up and down the lifter pins 14. The substrate table main body 8a also includes a resistance heating body 9 embedded therein. When the resistance heating body 9 is supplied with an electric power, the substrate table main body 8a is heated, so the target substrate W is heated. The substrate table main body 8a is made of a ceramic, such as AlN or Al₂O₃.

This substrate table 8 has the same structure as the substrate table 20 described above. Specifically, head portions 14a are respectively formed on the distal ends of the lifter pins 14, while recessed portions 8b are formed in the substrate table main body 8a at positions corresponding to the head portions 14a to partly accommodate the head portions 14a, as in the recessed portions 22b described above. The height of the head portion 14a and the depth of the recessed portion 8b are set for the upper side of the head portion 14a to protrude from the surface of the substrate table main body 8a in a state where the lifter pins 14 are set at the lower position and the head portion 14a sits in the recessed portion 8b. Specifically, in this state, the upper side of the head portion 14a protrudes from the surface of the substrate table main body 8a by a distance of more than 0.0 mm and 0.5 mm or less, preferably of 0.1 mm or more and 0.4 mm or less, and more preferably of 0.2 mm or more and 0.4 mm or less.

The substrate table 8 may be provided with a lower electrode embedded therein and connected to an RF power supply (not shown) through a matching box (not shown). In this case, the RF power supply may be configured to apply an RF of, e.g., 450 kH to 13.65 MHz to generate RF bias. Alternatively, a DC (direct current) power supply may be connected to generate a continuous bias.

A table fixing member 64 is disposed to support the substrate table 8 through a support member 16 or the like. The table fixing member 64 is made of, e.g., a metal, such as Al, or an alloy thereof, while the table support member 16 is made of a ceramic, such as AlN. The substrate table 8 and support member 16 are integrated or joined by brazing, so that this structure requires no vacuum seals or fixing screws. The bottom of the table support member 16 is fixed by screws or the like to a support member fixing portion 81 made of, e.g., a metal, such as Al, or an alloy thereof, through a fixing ring 80 made of, e.g., a metal, such as Al, or an alloy thereof, so that the gap between the support face of the substrate table 8 and the dielectric body plate 4 can be adjusted. The table support member 16 and support member fixing portion 81 are airtightly sealed by, e.g., an O-ring (not shown). The support member fixing portion 81 is fixed to the table fixing member 64 airtightly through, e.g., an O-ring (not shown).

The table fixing member 64 is fixed by screws to the sidewall of the exhaust pipe 77 airtightly through, e.g., an O-ring (not shown). Specifically, one side of the table fixing member 64 is connected to the inner sidewall of the exhaust pipe 77. The bottom of the table fixing member 64 is supported by a support member 84, which serves as a positioning member for positioning the substrate table 8 in a horizontal state through the table fixing member 64, in assembling after a maintenance operation. The support member 84 is inserted from outside airtightly through a fixing hole formed in the exhaust pipe 77 and is fixed to the exhaust pipe 77. The support member 84 is attached such that its distal end engages with a latch portion 68 at the bottom of the table fixing member 64, so that the table is easily set in a horizontal state.

The support member 84 serves as a positioning member. The position of the substrate table 8 is determined when the latch portion 68 at the bottom of the table fixing member 64 engages with an engagement portion prepared in advance at the distal end of the support member 84. For example, as shown in FIG. 8, the distal end of the support member 84 has a recess as the engagement portion formed on the upper side, while the latch portion 68 has a projection on the bottom, so that the projection can be inserted in the recess to fix their positions. In this case, the latch portion 68 may be fixed to the engagement portion of the support member 84 by a screw or bolt. Further, although not shown, the distal end of the support member 84 may have a hole as the engagement portion of the positioning member, so that a portion formed on the bottom of the table fixing member 64 can be inserted in this hole.

The table fixing member 64 has an internal space 71 that is opened to the sidewall of the exhaust pipe 77 and communicates with the atmospheric side through an opening portion 71a formed in the sidewall of the exhaust pipe 77. Further, the space 71 communicates with a space 94 inside the table support member 16 through a space 92 inside the support member fixing portion 81, so that all of them are opened to the atmospheric side.

The space inside the table fixing member 64 contains wiring lines, such as feed lines for supplying electric power to the resistance heating body embedded in the substrate table 8 and wiring lines of a thermocouple for measuring and controlling the temperature of the substrate table 8. Illustration of these wiring lines is omitted in FIG. 8. The wiring lines are extended through the space 94 of the table support member 16 and the space 71 of the table fixing member 64, and are then led out of the plasma processing apparatus 1 through the opening portion 71a of the flange.

Further, a cooling water passage 83 is formed inside the table fixing member 64 at a lower position, so that cooling water can be supplied from outside the plasma processing apparatus 100. The cooling water is supplied to prevent heat of the substrate table 8 from increasing the temperature of the table fixing member 64 through the table support member 16.

As described above, in the microwave plasma processing apparatus 1, the substrate table 8 is fixed to the exhaust pipe 77 at a plurality of positions. Specifically, the substrate table 8 is fixed to the table fixing member 64 at two positions on the lateral and bottom sides. The bottom side of the table fixing member 64 is fixed to the exhaust pipe 77 through the latch portion 68 and support member 84. The lateral side of the table fixing member 64 is fixed to the inner sidewall of the exhaust pipe 77. In other words, the substrate table 8 is fixed to the exhaust pipe 77 by fixing members disposed at two positions, so that it is fixed relative to the process container 10. After a maintenance operation is performed, the substrate table 8, table support member 16, support member fixing portion 81, table fixing member 64, and so forth are positioned by inserting the projection of the latch portion 68 into the recess formed at the distal end of the support member 84, so the substrate table 8 can be easily set in a horizontal state.

Inside the process container 10, a baffle plate 10a is disposed around the table 8 and has a plurality of holes for uniformly exhausting gas from inside the process container. The baffle plate 10a is supported by a baffle plate support member 10b made of a metal, such as aluminum or stainless steel. Further, a baffle plate 10d made of the same material as the baffle plate 10a, such as quartz, is disposed to prevent contamination. The inner wall of the process container 10 is covered with a quartz liner 10c to protect the process container 10. As described above, where a shield plate is disposed to shield the interior of the process container 10, a clean atmosphere can be formed.

The process container 10 has a transfer port 7a formed in the sidewall for loading and unloading the target substrate W. The transfer port 7a can be opened and closed by a gate valve 7.

In the microwave plasma apparatus 1 having the structure described above, when microwaves are supplied from the coaxial waveguide tube 52 to the radial line slot antenna 50, the microwaves are propagated outward in the radial direction in the antenna 50, and undergoes wavelength compression by the wave-retardation body 55. The microwaves are radiated from the slots 50a generally as circularly polarized waves essentially in a direction perpendicular to the radial slot antenna (planar antenna plate) 50.

On the other hand, nitrogen gas and oxygen gas are supplied along with a rare gas, such as Ar, Kr, Xe, or Ne from the rare gas source 101, nitrogen gas source 102, and oxygen gas source 103 through the ring-like gas injector 6 uniformly into the process space inside the process container 10. These gases are turned into plasma by microwaves radiated into the process space, so that a plasma process is performed on the target substrate W. Further, the process gases thus supplied are exhausted through the exhaust section 11.

The microwaves radiated into the process space has a frequency of the order of GHz, such as 2.45 GHz, and, when the microwaves described above are supplied, plasma with a high density of 10¹¹ to 10¹³/cm³ is excited above the target substrate W. Further, the plasma excited by the microwaves supplied from the antenna is characterized by an electron temperature of 0.5 to 7 eV or less. Consequently, the microwave plasma processing apparatus 1 can prevent the target substrate W and the inner wall of the process container 10 from being damaged. In addition, radicals generated by plasma excitation flow along the front side of the target substrate W and are swiftly exhausted from the process space. Consequently, recombination of the radicals is suppressed, so a substrate process can be performed very uniformly and effectively at a low temperature of 550° C. or less.

For example, where the experiment explained with reference to FIG. 4 or 6 is performed in the microwave plasma processing apparatus 1 shown in FIG. 8, the following conditions are used. Specifically, the substrate table main body 8a is heated to a temperature within a range of 100 to 600° C. The process space inside the process container 10 is pressure-decreased to a pressure within a range of 3 to 666.5 Pa. Ar gas is supplied at a flow rate of 500 to 2,000 mL/min (sccm) and oxygen gas is supplied at a flow rate of 5 to 500 mL/min (sccm) both from the gas injector 6. Further, microwaves having a frequency of 2.45 GHz are supplied at a power of 1 to 3 kW from the planar antenna 50.

At this time, according to this embodiment, the protrusion height of the lifter pins 14 from the main surface of the substrate table main body 8a is optimized as in the previous embodiment in a state where the lifter pins 14 is set at the lower position relative to the substrate table main body 8a. Specifically, in this state, the protrusion height is set to be more than 0.0 mm and 0.5 mm or less, preferably to be 0.1 mm or more and 0.4 mm or less, and more preferably to be 0.2 mm or more and 0.4 mm or less. Consequently, the particle generation is effectively suppressed as in the case explained with reference to FIG. 6.

The explanation described above is made, taking a microwave plasma processing apparatus as an example. However, a substrate table according to the present invention may be applied to a plasma process other than the microwave plasma process, such as a plasma process of the ICP type, ECR type, parallel-plate type, surface reflection wave type, or magnetron type. Further, a substrate table according to the present invention may be applied to a process other than the plasma process. Further, a substrate table according to the present invention may be applied to any one of various processes other than the oxidation process described above, such as a nitridation process, CVD process, or etching process. Further, the target object is not limited to a semiconductor wafer, and it may be another substrate, such as a glass substrate for FPD.

The upper surface of the head portion 24a of each of the lifter pins 24 shown in FIG. 5 may have a shape protruding upward, such as a conical shape, as shown in FIG. 10.

### Second Embodiment

Next, an explanation will be given of a second embodiment of the present invention.

FIG. 11 is a sectional view schematically showing a plasma processing apparatus according to the second embodiment of the present invention. As in the first embodiment, this plasma processing apparatus 200 is arranged as a plasma processing apparatus, in which microwaves are supplied from a planar antenna having a plurality of slots, such as an RLSA (Radial Line Slot Antenna), into a process chamber to generate plasma, so that microwave plasma is generated with a high density and a low electron temperature.

The plasma processing apparatus 200 includes an airtight chamber (process container) 201 for accommodating a wafer W, wherein the chamber 201 has an essentially cylindrical shape and is grounded. The chamber 201 comprises a housing member 202 made of a metal, such as aluminum or stainless steel, and forming the lower part of the chamber 201, and a chamber wall 203 disposed on the housing member 202. The chamber 201 is provided with a microwave feeder mechanism 230, in an openable/closable state, for supplying microwaves into the process space.

The bottom wall 202a of the housing member 202 has a circular opening portion 210 formed essentially at the center. The bottom wall 202a is provided with an exhaust chamber 211 communicating with the opening portion 210 and extending downward to uniformly exhaust gas from inside the chamber 201.

A susceptor 205 is located inside the housing member 202 to support a target substrate, such as a wafer W, in a horizontal state. The susceptor 205 is supported by a cylindrical support member 204 extending upward from the center of the bottom of the exhaust chamber 211. The susceptor 205 and support member 204 may be made of a material selected from quartz and ceramics, such as AlN and Al₂O₃. Of these materials, AlN is preferably used, because it has good thermal conductivity. The susceptor 205 is provided with a guide ring 208 located on the outer edge to guide the wafer W. The susceptor 205 is further provided with a heater (not shown) of the resistance heating type embedded therein. When the heater is supplied with a power from a heater power supply 206, the susceptor 205 is heated, so the target object or wafer W is heated. The temperature of the susceptor 205 is measured by a thermo couple 220 embedded in the susceptor 205. A temperature controller 221 is arranged to control the heater power supply 206 on the basis of signals transmitted from the thermo couple 220, so that the temperature can be controlled within a range of from room temperature to 1,000° C.

The susceptor 205 is provided with lifter pins (not shown) that can project and retreat relative to the surface of the susceptor 205 to support the wafer W and move it up and down. The outer periphery of the susceptor 205 is surrounded by an annular baffle plate 207, which is supported by a plurality of support rods 207a. The baffle plate 207 has a plurality of exhaust holes that allow the interior of the chamber 201 to be uniformly exhausted. A cylindrical liner 242 made of quartz is attached along the inner wall of the chamber 201 to prevent metal contamination due to the material of the chamber, thereby maintaining a clean environment. The liner 242 may be made of a ceramic (such as Al₂O₃, AlN, or Y₂O₃).

The sidewall of the exhaust chamber 211 is connected to an exhaust unit 224 including a high speed vacuum pump through an exhaust line 223. The exhaust unit 224 can be operated to uniformly exhaust gas from inside the chamber 201 into the space 211a of the exhaust chamber 211, and then out of the exhaust chamber 211 through the exhaust line 223. Consequently, the inner pressure of the chamber 201 can be decreased at a high speed to a predetermined vacuum level, such as 0.133 Pa.

The housing member 202 has a transfer port formed in the sidewall and provided with a gate valve for opening/closing the transfer port (they are not shown), so that the wafer W is transferred therethrough.

The sidewall of the chamber 201 has gas feed passages formed therein to supply a process gas into the chamber 201. Specifically, a step portion 218 is formed at the upper end of the sidewall of the housing member 202, while a step portion 219 is formed at the lower end of the chamber wall 203. As described later, an annular passage 213 is formed between the step portions 218 and 219.

The upper end of the chamber wall 203 engages with the microwave feeder mechanism 230, and the lower end of the chamber wall 203 is coupled to the upper end of the housing member 202. Gas passages 214 are formed in the chamber wall 203.

At the upper and lower junctions of the chamber wall 203, seal members 209a, 209b, and 209c, such as O-rings, are disposed to ensure that these junctions are airtight. The seal members 209a, 209b, and 209c are made of, e.g., fluorocarbon gum.

The chamber wall 203 has an annular projection 217 formed on the inner side at the lower end, which extends vertically downward like a skirt. The projection 217 covers the boundary (junction) between the chamber wall 203 and housing member 202 to prevent plasma from directly acting on the seal member 209b made of a material that can be easily deteriorated by plasma exposure. Further, the chamber wall 203 has the step portion 219 formed at the lower end, which is combined with the step portion 218 of the housing member 202 to form the annular passage 213.

Gas feed ports 215a are formed along the inner surface of the chamber wall 203 equidistantly at a plurality of positions of the upper end, (for example 32 positions). The gas feed ports 215a are connected to feed passages 215b extending therefrom in a horizontal direction. The gas feed passages 215b are connected to the gas passages 214 extending in the vertical direction in the chamber wall 203.

The gas passages 214 are connected to the annular passage 213, which is formed by the step portions 218 and 219 at the junction between the upper end of the housing member 202 and the lower end of the chamber wall 203. The annular passage 213 extends in an essentially horizontal annular direction to surround the process space. The annular passage 213 is connected to a gas supply unit 216 through passages 212 formed in the housing member 202 at certain positions (for example, at four positions uniformly separated) and extending in the vertical direction. The annular passage 213 serves as gas distribution means for supplying a process gas into the gas passages 214 in uniform distribution, thereby preventing the gas from being preferentially supplied into a specific one of the gas feed ports 215a.

As described above, according to this embodiment, a gas from the gas supply unit 216 is supplied through the passages 212, annular passage 213, and gas passages 214, and is uniformly delivered from the gas feed ports 215a at 32 positions into the chamber 201. Consequently, the uniformity of plasma generated inside the chamber 201 is improved.

The chamber 201 has an opening portion at the top, which is airtightly closed by a microwave feeder mechanism 230. The microwave feeder mechanism 230 can be opened/closed by an opening/closing mechanism (not shown).

The microwave feeder mechanism 230 includes a microwave transmission plate 228, a planar antenna member 231, and a wave-retardation body 233 laminated in this order from the susceptor 205 side. These members are covered with a shield member 234 and are fixed to the support portion of an upper plate 227 through a support member 236 along with an O-ring by an annular presser ring 235 having an L-shape in a cross section. When the microwave feeder mechanism 230 is closed, the portion between the upper end of the chamber 201 and the upper plate 227 is sealed by the seal member 209c, and the microwave feeder mechanism 230 is supported by the upper plate 227 through the transmission plate 228, as described later.

The microwave transmission plate 228 is made of a dielectric body, such as quartz, sapphire or a ceramic, e.g., Al₂O₃, AlN, or SiN. The microwave transmission plate 228 serves as a microwave introduction window for transmitting microwaves into the process space inside the chamber 201. The bottom surface of the microwave transmission plate 228 (on the susceptor 205 side) is not limited to a flat shape, and, for example, a recess or groove may be formed thereon to generate plasma uniformly and stably. The transmission plate 228 is airtightly supported through a seal member 229 by an annular projection 227a formed on the inner surface of the upper plate 227 below and around the microwave feeder mechanism 230. Accordingly, when the microwave feeder mechanism 230 is closed, the interior of the chamber 201 can be kept airtight.

The planar antenna member 231 is formed of a circular plate and is fixed to the inner peripheral surface of the shield member 234 above the transmission plate 228. For example, the planar antenna member 231 is formed of, e.g., a copper plate or aluminum plate with the surface plated with gold or silver. The planar antenna member 231 has a number of slot holes 232 formed therethrough and arrayed in a predetermined pattern, for radiating electromagnetic waves, such as microwaves.

For example, as shown in FIG. 12, the slot holes 232 are formed of long slits, wherein the slot holes 232 are typically arranged such that adjacent slot holes 232 form a T-shape, while they are arrayed on a plurality of concentric circles. The length and array intervals of the slot holes 232 are determined in accordance with the wavelength (λg) of microwaves. For example, the intervals of the slot holes 232 are set to be ¼ λg, ½ λg, or λg. In FIG. 12, the interval between adjacent slot holes 232 respectively on two concentric circles is expressed with Δr. The slot holes 232 may have another shape, such as a circular shape or arc shape. The array pattern of the slot holes 232 is not limited to a specific one, and, for example, it may be spiral or radial other than concentric.

The wave-retardation body 233 has a dielectric constant larger than that of vacuum, and is located on the top of the planar antenna member 231. For example, the wave-retardation body 233 is made of quartz, a ceramic, a fluorocarbon resin, e.g., polytetrafluoroethylene, or a polyimide resin. The wave-retardation body 233 shortens the wavelength of microwaves to adjust plasma, because the wavelength of microwaves becomes longer in a vacuum condition. The planar antenna member 231 may be set in contact with or separated from the transmission plate 228. Similarly, the wave-retardation body 233 may be set in contact with or separated from the planar antenna 231.

The shield member 234 is provided with cooling water passages 234a formed therein. Cooling water is supplied to flow through the cooling water passages and thereby cools the shield member 234, wave-retardation body 233, planar antenna member 231, transmission plate 228, and upper plate 227. Consequently, these members are prevented from being deformed or damaged, while plasma is stably generated. The shield member 234 is grounded.

Since an intense electric field is generated near the upper plate 227, the surface of the upper plate 227 is exposed to intense plasma and is worn out by a sputtering action of ions or the like. FIG. 13 is a view showing the relationship between the distance from the transmission plate 228 and the electron temperature of plasma. With an increase in the electron temperature, the energy of ions is increased and plasma attack (sputtering action of ions with high energy or the like) thereby becomes severer. As shown in FIG. 13, where the distance is less than 20 mm, the electron temperature is abruptly increased and the plasma attack thereby becomes severer. The upper plate 227 is located near the transmission plate 228, and particularly the projection 227a of the upper plate 227 can be very close to plasma, so the projection 227a suffers severe plasma attack and is notably worn out. If the upper plate 227 is made only of aluminum as conventionally used, a lot of aluminum contaminants are generated by wear-out of the surface due to plasma, and deteriorate the process. According to this embodiment made in light of the problem described above, as shown in the enlarged view of FIG. 14, the upper plate 227 is prepared to have a structure in which an aluminum main body 271 is coated with a silicon film 272 on the surface to be exposed to plasma, so that generation of aluminum contaminants is suppressed.

The silicon film 272 of the upper plate 227 is preferably set to have a thickness of about 1 to 100 μm. If the thickness is smaller than 1 μm, the aluminum main body 271 can be exposed in a short time, so the effect of the film is insufficient. If the thickness is larger than 100 μm, the film can be easily cracked or peeled off due to a stress.

The silicon film 272 may be formed by a thin film formation technique, such as PVD (physical vapor deposition) or CVD (chemical vapor deposition), or thermal spraying. Of them, thermal spraying is preferably used, because it can form a thick film at a relatively low cost. Specifically, according to the thermal spraying, a film formation material is melted or softened by heating and is changed into fine particles. Then, the fine particles are accelerated and sprayed onto a target surface, so that they are deposited flatly to form a film. The thermal spraying encompasses flame thermal spraying, arc thermal spraying, laser thermal spraying, and plasma thermal spraying. Of them, the plasma thermal spraying is preferably used, because a high purity film can be formed with high controllability. Further, in order to prevent oxidation of silicon, the thermal spraying is preferably performed under a vacuum pressure. Either crystal or amorphous is acceptable as the structure of the silicon film 272 thus formed.

The shield member 234 has an opening portion 234b formed at the center of the upper wall and connected to a waveguide tube 237. The waveguide tube 237 is connected to a microwave generation unit 239 at one end through a matching circuit 238. The microwave generation unit 239 generates microwaves with a frequency of, e.g., 2.45 GHz, which are transmitted through the waveguide tube 237 to the planar antenna member 231. The microwaves may have a frequency of 8.35 GHz or 1.98 GHz.

The waveguide tube 237 includes a coaxial waveguide tube 237a having a circular cross-section and extending upward from the opening portion 234b of the shield member 234, and a rectangular waveguide tube 237b connected to the upper end of the coaxial waveguide tube 237a through a mode transducer 240 and extending in a horizontal direction. Microwaves are propagated in a TE mode through the rectangular waveguide tube 237b, and are then turned into a TEM mode by the mode transducer 240 interposed between the rectangular waveguide tube 237b and coaxial waveguide tube 237a. The coaxial waveguide tube 237a includes an inner conductive body 241 extending at the center, which is connected and fixed to the center of the planar antenna member 231 at the lower end. Consequently, microwaves are efficiently and uniformly propagated from the inner conductive body 241 of the coaxial waveguide tube 237a in the radial direction to the planar antenna member 231.

Next, an explanation will be given of an operation of the plasma processing apparatus 200 having the structure described above.

At first, a wafer W is loaded into the chamber 201 and placed on the susceptor 205. Then, process gases are supplied at predetermined flow rates from the gas supply unit 216 through the gas feed ports 215a into the chamber 201. Examples of the process gases are a rare gas, such as Ar, Kr, or He, and an oxidizing gas such as O₂, N₂O, NO, NO₂, or CO₂, or a nitride gas such as N₂ or NH₃. The process gases may be formed of other film formation gases or etching gases.

Then, microwaves are supplied from the microwave generation unit 239 through the matching circuit 238 into the waveguide tube 237. The microwaves are guided through the rectangular waveguide tube 237b, mode transducer 240, and coaxial waveguide tube 237a in this order, and are then propagated through the inner conductive body 241 to the planar antenna member 231. Then, the microwaves are radiated from the slots of the planar antenna member 231 through the transmission plate 228 into the chamber 201.

The microwaves are propagated in a TE mode through the rectangular waveguide tube 237b, and are then turned from the TE mode into a TEM mode by the mode transducer 240 and propagated in the TEM mode through the coaxial waveguide tube 237a to the planar antenna member 231. When the microwaves are radiated from the planar antenna member 231 through the transmission plate 228 into the chamber 201, the process gases are turned into plasma by the microwaves.

Since microwaves are radiated from a number of slot holes 232 of the planar antenna member 231, this plasma has a high density of about 1×10¹⁰ to 5×10¹²/cm³ and a low electron temperature of about 1.5 eV or less near the wafer W. Accordingly, where this plasma acts on the wafer W, the process can be performed while suppressing plasma damage.

When plasma is generated as described above, as shown in FIG. 15B, the surface of the upper plate 227 present in the plasma generation area S is exposed to intense plasma. Conventionally, as shown in FIG. 15A, an upper plate 227′ made of aluminum has no coating of a silicon film, so the aluminum is worn out and aluminum contaminants are generated.

On the other hand, according to this embodiment, as shown in FIG. 15B, the upper plate 227 is formed of the aluminum main body 271 coated with the silicon film 272 on the surface to be exposed to plasma. In this case, only the silicon film 272 is worn out by plasma, and the aluminum of the main body 271 can be hardly worn out. Consequently, the process is prevented from being deteriorated by aluminum contaminants, and is also prevented from lowering the reproducibility due to the upper plate being degraded by plasma. Further, where the silicon film 272 is formed by thermal spraying, and preferably by plasma thermal spraying, a thick film can be formed relatively easily at a low cost.

As in Jpn. Pat. Appln. KOKAI Publication No. 2002-353206 described above, if the upper plate is formed of a processed bulk body of mono-crystalline silicon, this part becomes very expensive but cannot have a sufficient strength, so this is not practical. Alternatively, an upper plate may be prepared by bonding a silicon bulk body on a main body. However, in this case, an interstice is inevitably formed between the silicon bulk body and main body, and abnormal electric discharge may be caused in the interstice. Further, alumina or yttria having a high plasma resistance may be used as the coating material, but such an insulating material can be easily charged up, so abnormal electric discharge may be locally caused.

On the other hand, according to this embodiment, the upper plate 227 is formed of the main body 271 coated with the silicon film 272, so the contamination problem can be solved without causing the problem described above.

Next, an explanation will be given of results of comparison in terms of aluminum contamination in a plasma process, between an upper plate formed of an aluminum main body coated with a thermal spraying silicon film and a conventional upper plate made of aluminum with no thermal spraying coating film. At this time, the silicon thermal spraying was performed by plasma thermal spraying, and the thickness of the thermal spraying film was set at 80 μm. In the plasma process, Ar gas, O₂ gas, and H₂ gas were supplied as the plasma gas at flow rates of Ar/O₂/H₂=1000/50/40 (mL/min (sccm)). The plasma generation electric power was set at 3,400 W. The pressure inside the chamber was set at 6.65 Pa (50 mTorr). The process time was set at 210 seconds. Under these conditions, the plasma process was performed continuously on 11 wafers. FIG. 16 shows results of this experiment.

As shown in FIG. 16, where the aluminum upper plate was used, the aluminum contamination (Al contamination) was 10¹¹ atoms/cm² or more. Where the upper plate coated with a thermal spraying silicon film was used, the aluminum contamination was lower than 10¹¹ atoms/cm². The thermal spraying coating film formed as described above was good in adhesion, and abnormal electric discharge was not caused due to film peeling or the like.

In this embodiment, as a member having a surface to be exposed to plasma is exemplified by the upper plate, wherein the silicon film is formed on the surface of the upper plate. Alternatively, this structure can be applied to another member having a surface to be exposed to plasma, such as a chamber wall, wherein the silicon film is formed on the surface of the chamber wall. In this embodiment, the main body of the upper plate or a member to be exposed to plasma is made of aluminum, but the same effect can be utilized even where the main body is made of another metal, such as stainless steel. Further, in this embodiment, the plasma processing apparatus is exemplified by a plasma processing apparatus of the RLSA type, but the structure according to this embodiment may be applied to a plasma processing apparatus of another type, such as the remote plasma type, ICP type, ECR type, surface reflection wave type, or magnetron type. The plasma process content is not limited to a specific one, and the structure according to this embodiment may be applied to various plasma processes, such as oxidation process, nitridation process, oxynitridation process, film formation process, and etching process. Further, the target object is not limited to a semiconductor wafer, and it may be another substrate, such as a glass substrate for FPD.

In the first embodiment, a member having a surface to be exposed to plasma, such as the upper plate 61, may be covered with a silicon coating. In the second embodiment, the structure associated with the lifter pins and the structure associated with the substrate table or susceptor may be modified in accordance with the lifter pins 24 or 14 and substrate table main body 22 or 8a of the first embodiment.

The present invention has been described with reference to embodiments, but the present invention is not limited to the embodiments described above, and it may be modified in various manners within the scope of the claims. Further, the present invention should be construed to encompass arrangements obtained by suitably combining some of the components of the embodiments described above or excluding some of the components of the embodiments described above, as long as they do not depart from the spirit or scope of the present invention.

1. A substrate processing apparatus for performing a predetermined plasma process on a target substrate, the apparatus comprising:
a process container configured to accommodate the target substrate;
a gas feed passage configured to supply a process gas into the process container;
an exhaust passage configured to exhaust gas from inside the process container;
a plasma generation mechanism configured to generate plasma of the process gas inside the process container; and
a metal component to be exposed to plasma inside the process container,
wherein the metal component is provided with a silicon film that coats at least a portion thereof to be exposed to plasma and to suffer an intense electric field generated thereabout.

2. The substrate processing apparatus according to claim 1, wherein the metal component consists essentially of aluminum or stainless steel.

3. The substrate processing apparatus according to claim 1, wherein the silicon film is a film formed by plasma thermal spraying.

4. The substrate processing apparatus according to claim 1, wherein the silicon film has a thickness of 1 to 100 μm.

5. The substrate processing apparatus according to claim 1, wherein the plasma generation mechanism comprises a planar antenna with a plurality of slots formed therein to radiate microwaves, a microwave transmission plate consisting essentially of a dielectric body and configured to transmit microwaves radiated from the planar antenna into the process container, and a support member made of the metal component and configured to support the microwave transmission plate, such that the support member is provided with the silicon film that coats a portion thereof to be exposed to plasma.

6. The substrate processing apparatus according to claim 1, wherein the plasma generation mechanism is of an ECR (electron cyclotron resonance) type, ICP (inductively coupled plasma) type, parallel-plate type, surface reflection wave type, or magnetron type as a type of plasma generation.

7. The substrate processing apparatus according to claim 1, wherein the silicon film is crystal or amorphous.

8. The substrate processing apparatus according to claim 5, wherein the portion of the support member to be exposed to plasma is a portion present at a distance of less than 20 mm from the microwave transmission plate.

9. The substrate processing apparatus according to claim 5, wherein the support member includes an annular support portion extending inward inside the process container, such that the microwave transmission plate is supported on the annular support portion, and the annular support portion is coated with the silicon film.

10. The substrate processing apparatus according to claim 9, wherein the gas feed passage includes a plurality of gas feed ports opened directly below the annular support portion.

11. A substrate processing apparatus for performing a plasma process on a target substrate, the apparatus comprising:
a process container configured to hold a vacuum therein and perform the plasma process on the target substrate accommodated therein, the process container including a container casing that defines a surrounding sidewall with a top opening and a dielectric transmission plate supported by the container casing and airtightly closing the top opening;
a worktable configured to place the target substrate thereon inside the process container;
a planar antenna disposed above the transmission plate and including a plurality of slots to supply microwaves from the slots through the transmission plate into the process container;
a gas feed passage configured to supply a process gas, to be turned into plasma by the microwaves, into the process container; and
an exhaust passage configured to exhaust gas from inside the process container,
wherein the chamber casing includes an annular support portion extending inward from the surrounding sidewall, such that the transmission plate is supported on the annular support portion, and the annular support portion is made of a metal and coated with a silicon film that protects the annular support portion from sputtering of ions derived from the plasma.

12. The substrate processing apparatus according to claim 11, wherein the annular support portion is defined by a lower side, a rising side, and an upper side, such that the transmission plate is supported on the upper side of the annular support portion, and the annular support portion is coated with the silicon film at least at the rising side and the upper side.

13. The substrate processing apparatus according to claim 11, wherein the surrounding sidewall includes an upper plate made of the metal and having an annular inner face on which the annular support portion is integrally formed, and a lower wall prepared individually relative to the upper plate an supporting the upper plate, and the annular inner face of the upper plate is coated with the silicon film.

14. The substrate processing apparatus according to clam 13, wherein the apparatus further comprises a liner disposed inside the lower wall, and the annular support portion extending inward further relative to the liner without being covered by the liner.

15. The substrate processing apparatus according to claim 11, wherein the gas feed passage includes a plurality of gas feed ports opened directly below the annular support portion.

16. The substrate processing apparatus according to claim 11, wherein the annular support portion consists essentially of aluminum or stainless steel.

17. The substrate processing apparatus according to claim 11, wherein the silicon film is a film formed by plasma thermal spraying.

18. The substrate processing apparatus according to claim 11, wherein the silicon film has a thickness of 1 to 100 μm.
